(19) United States
(12) Patent Application Publication
(10) Pub. No.: US 2018/0315629 A1
(43) Pub. Date: Nov. 1, 2018

(54) TRANSFER APPARATUS AND TRANSFER METHOD

(71) Applicant: TOKYO ELECTRON LIMITED, Tokyo (JP)

(72) Inventor: Masato KON, Miyagi (JP)

(73) Assignee: TOKYO ELECTRON LIMITED, Tokyo (JP)

(21) Appl. No.: 15/961,235

(22) Filed: Apr. 24, 2018

(30) Foreign Application Priority Data
Apr. 28, 2017 (JP) 2017-090011

(51) Int. Cl. H01L 21/67; H01L 21/677

(52) U.S. Cl. CPC H01L 21/67196; H01L 21/67742; H01L 21/67017; H01L 21/67201; H01L 21/67167

(57) ABSTRACT

A transfer apparatus includes a transfer chamber to which a target object of a processing chamber is transferred, and an ionic liquid, held on an inner wall of the transfer chamber. The ionic liquid adsorbs particles in an atmosphere in the transfer chamber.

### CROSS-REFERENCE TO THE RELATED APPLICATION

This application claims priority to Japanese Patent Application No. 2017-090011 filed on Apr. 28, 2017, the entire contents of which are incorporated herein by reference.

### FIELD OF THE INVENTION

The disclosure relates to a transfer apparatus and a transfer method.

### BACKGROUND OF THE INVENTION

As an example, in a processing chamber of a semiconductor manufacturing apparatus, predetermined processing is performed on a substrate (target object) by activating a gas. During the processing of the substrate, a reaction product is generated and the generated reaction product is adhered and deposited onto an inner wall or the like of the processing chamber. The reaction product is peeled off from the inner wall or the like and becomes particles. The particles are adhered to the substrate, thereby causing product defects.

Therefore, in the related art, e.g., Japanese Patent Application Publication No. 2009-68071, there is known a technique for suppressing film formation on the inner wall of the processing chamber by using an anti-adhesion plate provided to partition a film forming material and the inner wall in order to prevent particles released from the film forming material during the film formation from being adhered to the inner wall. In another related art, e.g., Japanese Patent Application Publication No. 2012-67342, there is known a technique for suppressing film formation on the inner wall of the processing chamber by allowing liquid to flow along the inner wall.

When a processed substrate is transferred from the processing chamber, the gas in the processing chamber is diffused toward an adjacent transfer chamber. Accordingly, the reaction product is gradually deposited inside the transfer chamber. The reaction product is also generated by the gas released from the substrate that is being transferred, and also deposited inside the transfer chamber. In the transfer chamber, a relatively small amount of reaction product is gradually deposited onto an inner wall of the transfer chamber as time elapses and, further, particles generated from the reaction product deposited onto the inner wall of the processing chamber scatter. The particles scattered in an atmosphere in the transfer chamber are adhered to the substrate that is being transferred, and product defects may occur during the transfer of the substrate.

### SUMMARY OF THE INVENTION

In view of the above, the disclosure provides a technique for suppressing the adhesion of particles onto a target object.

In accordance with an aspect of the present disclosure, there is provided a transfer apparatus including: a transfer chamber to which a target object of a processing chamber is transferred; and an ionic liquid, held on an inner wall of the transfer chamber, configured to absorb particles in an atmosphere of the transfer chamber.

In accordance with an aspect of the present disclosure, the adhesion of the particles onto the target object can be suppressed.

### BRIEF DESCRIPTION OF THE DRAWINGS

The objects and features of the disclosure will become apparent from the following description of embodiments, given in conjunction with the accompanying drawings, in which:

FIG. 1 is a top view schematically showing an exemplary configuration of a semiconductor manufacturing apparatus according to an embodiment;

FIG. 2 is a side view schematically showing the exemplary configuration of the semiconductor manufacturing apparatus according to the embodiment;

FIG. 3 is a top view schematically showing an example of a transfer unit according to an embodiment;

FIG. 4 is an enlarged view schematically showing an example of an inner wall of a transfer chamber in an embodiment;

FIG. 5 is an enlarged view schematically showing another example of the inner wall of the transfer chamber in the embodiment;

FIG. 6A explains a total number of particles in an atmosphere in a reference embodiment; and

FIG. 6B explains a total number of particles in an atmosphere in an embodiment.

### DETAILED DESCRIPTION OF THE EMBODIMENTS

Hereinafter, embodiments will be described with reference to the drawings. A transfer apparatus and a transfer method of the present disclosure are not limited by the following embodiments. Like reference numerals will be used for substantially like parts throughout this specification and the drawings, and redundant description thereof will be omitted.

(Overall Configuration of the Semiconductor Manufacturing Apparatus)

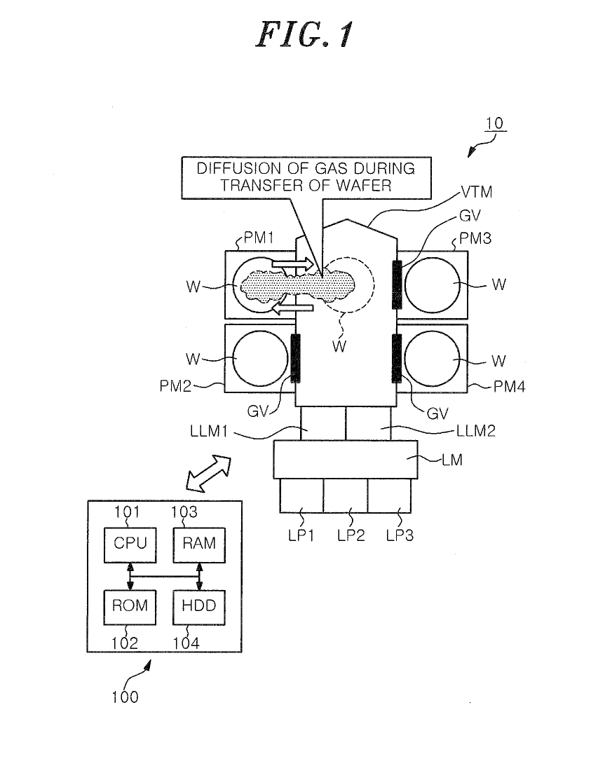

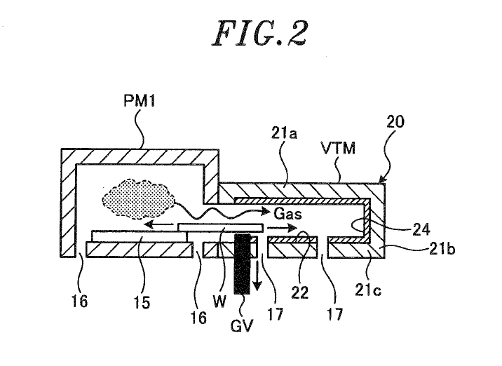

FIG. 1 is a top view schematically showing an exemplary configuration of a semiconductor manufacturing apparatus according to an embodiment. FIG. 2 is a side view schematically showing the exemplary configuration of the semiconductor manufacturing apparatus according to the embodiment. First, an example of an overall configuration of a semiconductor manufacturing apparatus 10 according to an embodiment will be described with reference to FIGS. 1 and 2. The semiconductor manufacturing apparatus 10 shown in FIG. 1 is a cluster structure (multi-chamber type) system.

As shown in FIGS. 1 and 2, the semiconductor manufacturing apparatus 10 of the embodiment includes process modules PM1 to PM4, a vacuum transfer module VTM, load-lock modules LLM1 and LLM2, a loader module LM, load ports LP 1 to 3, and a control unit 100. In the processing chamber PM, the desired processing is performed on a semiconductor wafer W (hereinafter, also referred to as “wafer W”) as a target object.

The process modules PM1 to PM4 are arranged near the vacuum transfer module VTM. The process modules PM1 to PM4 and the vacuum transfer module VTM communicate with each other by opening and closing gate valves GV. The process modules PM1 to PM4 are depressurized to a predetermined vacuum atmosphere. The wafer W is subjected to etching, film formation, cleaning, ashing or the like inside the process modules PM1 to PM4.

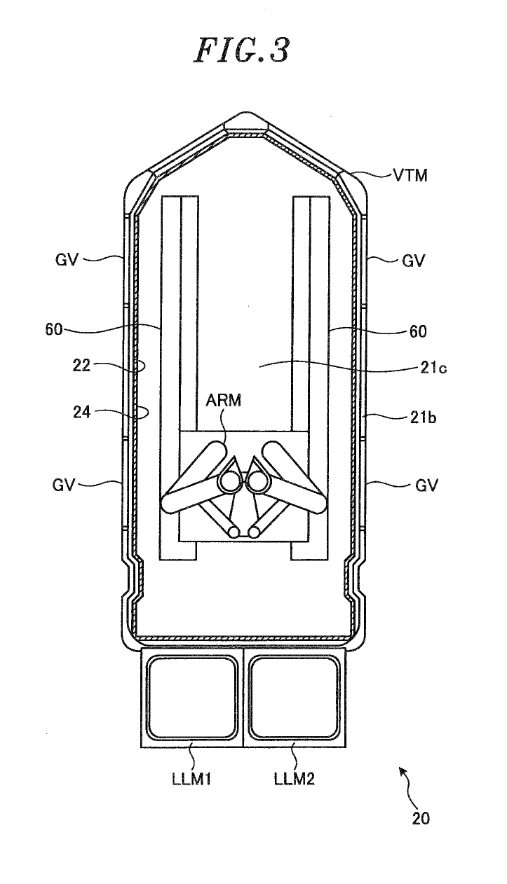

FIG. 3 is a top view schematically showing an exemplary configuration of a transfer apparatus according to an embodiment. As shown in FIG. 3, a handling device ARM (Advanced Robot Module) is provided as a transfer mechanism for transferring the wafer W in the vacuum transfer module VTM. The handling device ARM has two robot arms capable of bending, stretching and rotating. Picks capable of holding the wafer W are provided at leading end portions of the robot arms. A slide portion 60 on which the handling device ARM is slidably moved is provided on a bottom surface 21c in the vacuum transfer module VTM. The handling device ARM performs loading and unloading of the wafer W while slidably moving between the process modules PM1 to PM4 and the vacuum transfer module VTM by the operation of opening and closing the gate valves GV. Further, the handling device ARM performs the loading and the unloading of the wafer W into and from the load-lock modules LLM1 and LLM2.

As shown in FIG. 1, the load-lock modules LLM1 and LLM2 are provided between the vacuum transfer module VTM and the loader module LM. An atmosphere in the vacuum transfer module VTM is switched between an atmospheric pressure and a vacuum pressure by evacuating the load-lock modules LLM1 and LLM2 from an atmospheric pressure to a vacuum state or vice versa. The load-lock modules LLM1 and LLM2 transfer the wafer W from the loader module LM of an atmospheric pressure side to the vacuum transfer module VTM of a vacuum pressure side or from the vacuum transfer module VTM of the vacuum pressure side to the loader module LM of the atmospheric pressure side by switching an atmosphere in the vacuum transfer module VTM between an atmospheric atmosphere and a vacuum atmosphere.

Load ports LP1 to LP3 are provided on a long sidewall of the loader module LM. A FOUP (Front Opening Unified Pod) accommodating, e.g., 25 wafers W, or an empty FOUP is attached to the load ports LP1 to LP3. The loader module LM loads the wafer W unloaded from the FOUP in the load ports LP1 to LP3 into any one of the load-lock modules LLM1 and LLM2. Further, the loader module LM accommodates the wafer W unloaded from any of the load-lock modules LLM1 and LLM 2 in the FOUP in the load ports LP1 to LP3.

The control unit 100 includes a CPU (Central Processing Unit) 101, a ROM (Read Only Memory) 102, a RAM (Random Access Memory) 103, and a HDD (Hard Disk Drive) 104. The control unit 100 may have another storage area such as a SSD (Solid State Drive) or the like, other than the HDD 104. The storage areas of the HDD 104, the RAM 103 and the like store therein manufacturing information in which process procedures, process conditions and transfer conditions are set.

The CPU 101 controls the processing of the wafer W in each process module PM based on the manufacturing information and controls the transfer operation of the wafer W. The HDD 104 and the RAM 103 may store a program for executing a substrate transfer process to be described later. The program for executing the substrate transfer process may be stored in and read out from a storage medium or may be provided from an external device through a network.

The number of process modules PM, vacuum transfer modules VTM, load-lock modules LLM, loader modules LM, and load ports LP are not limited to the number described in the present embodiment and may be arbitrarily set. The transfer apparatus 20 of the embodiment includes, e.g., the vacuum transfer module VTM, the load-lock module LLM, the loader module LM, and the handling device ARM. In other words, the transfer apparatus 20 of the embodiment has a first transfer chamber adjacent to the process modules PM1 to PM4 and a second transfer chamber that is not adjacent to the process modules PM1 to PM4. The vacuum transfer module VTM is an example of the first transfer chamber. The load-lock module LLM and the loader module LM are examples of the second transfer chamber.

### (Holding State of the Ionic Liquid)

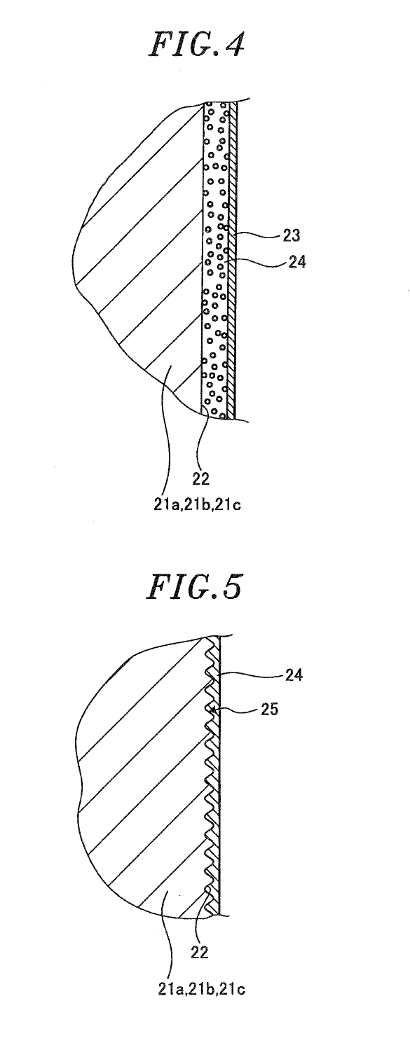

FIG. 4 is an enlarged view schematically showing an example of the inner wall of the vacuum transfer module VTM in an embodiment. As shown in FIGS. 2 and 3, the vacuum transfer module VTM is formed in a box shape having six surfaces, and ionic liquid 23 for absorbing particles in an atmosphere in the vacuum transfer module VTM is held in the inner walls 22 of a top surface 21a, a side surface 21b, and the bottom surface 21c. As shown in FIG. 4, for example, the ionic liquid 23 is held by a liquid holding member 24 that is attached to the inner walls 22 in the vacuum transfer module VTM. The ionic liquid 23 is held in an impregnated state by the liquid holding member 24, where the liquid holding member 24 may be a porous material such as paper, a sponge sheet or the like. For the paper, a clean paper (dust free paper) used for a clean room is used. As for the clean paper, “Stacrin” (trademark) manufactured by Sakurai Co., Ltd. may be used.

As an example, in the case of using paper such as a clean paper or the like, since the paper has fine pores, the ionic liquid 23 can be properly held in the fine pores of the paper. In addition, since one pore of the paper extensively communicates with other pores thereof in a mesh shape, when the ionic liquid 23 fills the pores, particles adhered to the ionic liquid 23 on the surface of the paper can be taken into the inside of the paper. Accordingly, a sufficient amount of particles can be taken into the pores. Further, in the case of using paper, the paper can be easily processed into any shape due to its flexibility and can be adhered along the inner wall 22 of the vacuum transfer module VTM having a complicated shape. Accordingly, it is possible to easily adhere the paper impregnated with the ionic liquid 23 over the entire inner wall 22 of the vacuum transfer module VTM.

Further, in the case of using paper, the paper impregnated with the ionic liquid 23 can be easily adhered directly to the inner wall 22 of the vacuum transfer module VTM by using the adsorption force from capillary action in which the paper sucks the ionic liquid 23 and also can be easily peeled off from the inner wall 22. Accordingly, the ionic liquid 23 can be easily handled. In the case where the paper impregnated with the ionic liquid 23 is attached onto the top surface 21a, even if a lightweight paper is partially peeled off, the possibility of the paper falling from the top surface 21a is low. Therefore, in the case of using paper as the liquid holding member 24, a fixing structure for fixing the liquid holding member 24 to the inner wall 22 becomes unnecessary and the liquid holding member 24 can be easily attached. In the case of using a lightweight sponge sheet as the liquid holding member 24, the sponge sheet may be attached to the inner wall 22 by using the adsorption force from the viscosity of the ionic liquid 23.

FIG. 5 is an enlarged view schematically showing another example of the inner wall of the vacuum transfer module VTM in the embodiment. Instead of using the liquid holding member 24, irregularities 25 where the ionic liquid 23 can be properly held without flowing may be formed on the surface of the inner wall 22 of the vacuum transfer module VTM as shown in FIG. 5. For example, by coating the ionic liquid 23 on the surface of the inner wall 22 of the vacuum transfer module VTM, the ionic liquid 23 adhered to the irregularities 25 is held. The irregularities 25 are formed to have a predetermined surface roughness by various surface treatments so that a proper amount of the ionic liquid 23 can be held on the surface of the inner wall 22 of the vacuum transfer module VTM, e.g., a proper film thickness can be maintained.

It is preferable that the ionic liquid 23 is provided over the entire surface of the inner wall 22 of the vacuum transfer module VTM by providing the liquid holding member 24 or the irregularities 25. Accordingly, particles in an atmosphere in the vacuum transfer module VTM are effectively adsorbed by the ionic liquid 23, suppressing the adhesion of particles onto the wafer W. Although the ionic liquid 23 may not be held at certain areas of the inner wall 22 of the vacuum transfer module VTM, e.g., the gate valves GV, gas exhaust openings 16 and gas exhaust port 17, the gas inlet port, various sensor attachment ports, or the like in the vacuum transfer module VTM, the expression “the ionic liquid 23 is provided on the entire surface of the inner wall 22” indicates that “the ionic liquid 23 is provided over substantially the entire surface of the inner wall 22”.

Depending on the location of the inner wall 22 of the vacuum transfer module VTM, the liquid holding member 24 may be provided at a part of the inner wall 22 and, also, the irregularities 25 may be formed at a part of the inner wall 22. For example, the liquid holding member 24 impregnated with the ionic liquid 23 may be adhered to a portion where it is relatively difficult to coat the ionic liquid 23 due to the shape of the inner wall 22 or the like, and the irregularities 25 may be formed at a portion where it is relatively easy to coat the ionic liquid 23.

Although it is not illustrated, the liquid holding member 24 holding the ionic liquid 23 may be provided on an outer peripheral surface of a case, e.g., on an outer peripheral surface of the robot arm, in the handling device ARM as a transfer mechanism. Accordingly, particles in an atmosphere corresponding to a movement range of the robot arm of the handling device ARM can be effectively adsorbed and removed by the ionic liquid 23 impregnated in the liquid holding member 24. The liquid holding member 24 may be provided on an outer peripheral surface of a structure provided in the vacuum transfer module VTM or may be provided on an outer peripheral surface of another device other than the handling device ARM.

### (Example of the Ionic Liquid)

The ionic liquid 23 does not volatilize even in a vacuum atmosphere and thus can be maintained in a liquid state in the vacuum atmosphere of the vacuum transfer module VTM. Therefore, the adhesion of volatile components or decomposed products of the ionic liquid 23 to the wafer W transferred in the vacuum transfer module VTM does not occur. As for the ionic liquid 23, one that is hydrophobic and water-insoluble and does not react with water (moisture) is used.

By using the ionic liquid 23 that is hydrophobic and water-insoluble and does not react with water, moisture can be prevented from being taken into the ionic liquid 23. Depending on the usage state of the vacuum transfer module VTM as in the present embodiment, the inner wall 22 of the vacuum transfer module VTM may be exposed to an atmospheric atmosphere. In that case, moisture contained in the atmospheric atmosphere is taken into the ionic liquid 23, and the moisture in the ionic liquid 23 is released into the vacuum atmosphere when the inner space of the vacuum transfer module VTM is evacuated. Accordingly, the vacuum degree in the vacuum transfer module VTM may be affected. Depending on the speed at which moisture taken into the ionic liquid 23 is released from the ionic liquid 23, the time required for evacuating the vacuum transfer module VTM may be increased. Further, moisture released from the ionic liquid 23 is adhered to the wafer W before the processing in the process module PM and, thus, the characteristics of the wafer W may be changed. In addition, the viscosity (viscosity rate) of the ionic liquid 23 is changed by the taken moisture. Accordingly, it is difficult to properly maintain the state in which the ionic liquid 23 is held on the inner wall 22 of the vacuum transfer moisture VTM. For example, as the viscosity of the ionic liquid 23 is decreased, the ionic liquid 23 disposed on the inner wall 22 of the side surface 21b of the vacuum transfer module VTM falls downward due to gravity.

In regard to the processing performed in the process module PM, it is preferable not to use ions with halogen elements as anions in order to prevent contamination. Since the vacuum transfer module VTM may be exposed to the atmospheric atmosphere, it is preferable not to use ionic liquid 23 that would chemically react with moisture contained in the atmospheric atmosphere. For example, ionic liquid 23 using PF₆— or BF₄— as anions generates hydrofluoric acid (HF) by reaction with water. Therefore, it is preferable not to use ionic liquid 23 using PF₆— or BF₄— as anions in consideration of the effect on the environment, human body and the durability of the vacuum transfer module VTM.

By using ionic liquid 23 that is hydrophobic and water-insoluble and does not react with water, it is possible to suppress the decrease in the vacuum degree in the vacuum transfer module VTM and the decrease in the holding force of the liquid holding member 24 that is caused by the decrease in the viscosity of the ionic liquid 23. In addition, since the reaction between the ionic liquid 23 and water is avoided, the effect on the environment and the human body is suppressed and the durability of the vacuum transfer module VTM is properly ensured.

The vacuum transfer module VTM may be used at room temperature. Therefore, it is preferable to use ionic liquid 23 that is in a liquid state at room temperature. In order to properly ensure an optimal range (process window) for manufacturing conditions, it is preferable to use an ionic liquid 23 having the lowest melting point and the highest boiling point.

As for optimal ionic liquids 23, there is used at least one among, e.g., methyltrioctylammonium thiosalicylate, trihexyltetradecylphosphonium bis (2-ethylhexyl) phosphate, methyl trioctyl ammonium bis (trifluoromethylsulfonyl) imide, 1-ethyl-3-methylimidazolium bis (trifluoromethylsulfonyl) imide, 1-butyl-3-methylimidazolium bis (trifluoromethylsulfonyl) imide, 1-hexyl-3-methylimidazolium bis (trifluoromethylsulfonyl) imide and 1-methyl-1-propylpyrrolidinium bis (trifluoromethylsulfonyl) amide.

On the inner wall 22 of the vacuum transfer module VTM, depending on the location of the inner wall 22, e.g., depending on the state of distribution of particles scattering in an atmosphere in the vacuum transfer module VTM, different types of ionic liquids 23 having different viscosities may be arranged by the liquid holding member 24. For example, by providing an ionic liquid 23 with relatively high viscosity near a space where the scattering of particles is relatively large, and by providing an ionic liquid 23 with relatively low viscosity near a space where the scattering of the particles is relatively small, the adsorption amount of particles depending on the viscosity of the ionic liquid 23 is properly set without excess or deficiency and the particles in an atmosphere in the vacuum transfer module VTM are properly adsorbed and removed. The inner wall where the ionic liquid 23 is held is not limited to the inner wall 22 of the vacuum transfer module VTM, and may be the inner wall of the load-lock chamber LLM, the inner wall of the loader module LM, or the like. In other words, the ionic liquid 23 is not necessarily used in a vacuum atmosphere, and the same effect is obtained even when the ionic liquid 23 is used in the loader-module LM in an atmospheric atmosphere due to its nonvolatility.

### (Transfer Operation of the Wafer W)

Next, the transfer operation of the wafer W and the diffusion of the gas will be described. First, the wafer W is unloaded from one of the load ports LP1 to LP3 and transferred to one of the load-lock chambers LLM1 and LLM2 via the loader module LM. In any one of the load-lock chambers LLM1 and LLM2 into which the wafer W is loaded, a gas exhaust process (evacuation) is performed and, thus, an atmosphere therein is switched from an atmospheric atmosphere to a vacuum atmosphere. In the vacuum state, the wafer W is unloaded from any one of the load-lock chambers LLM1 and LLM2 by the handling device ARM and then loaded into any one of the process modules PM1 to PM4, where the wafer W is then processed. The atmosphere in any one of the load-lock modules LLM1 and LLM 2 from which the wafer W has been unloaded is switched from a vacuum atmosphere to an atmospheric atmosphere.

Hereinafter, an example of the case in which the wafer W is supplied to the process module PM1 and subjected to plasma etching will be described.

(Example of the Process Condition) gas: CF₄ (carbon tetrafluoride), C₄F₈ (perfluorocyclobutane), Ar (argon), N₂ (nitrogen), H₂ (hydrogen), O₂ (oxygen), NO₂ (nitrogen dioxide)

pressure: 10 mT (1.333 Pa) to 50 mT (6.666 Pa)

processing time: about 5 minutes per single wafer processing

A plasma is generated from the gas in the processing chamber PM1, and the wafer W mounted on the mounting table in the process module PM1 is etched by the plasma as shown in FIG. 2. After processing, the inside of the process module PM1 is purged by N₂ gas. The N₂ gas is exhausted from the gas exhaust port 16 of the process module PM1.

Thereafter, the gate valve GV is opened, and the processed wafer W is loaded into the vacuum transfer module VTM. Further, an unprocessed wafer W is loaded into the process module PM1. During the transfer of the wafer W, the gas in the process module PM1 is diffused toward the vacuum transfer module VTM adjacent to the process module PM1. The gas is also released from the wafer W transferred into the vacuum transfer module VTM.

After the gate valve GV is closed, the inside of the vacuum transfer module VTM is purged by N₂ gas. As shown in FIG. 2, the N₂ gas is exhausted from the gas exhaust port 17 of the vacuum transfer module VTM. Accordingly, the gas diffused from the process module PM1 and the outgas released from the wafer W are exhausted from the gas exhaust port 17. However, a part of the gas remains in the vacuum transfer module VTM. Therefore, as time elapses, a small amount of reaction products, compared to that in the process module PM1, tends to be gradually deposited in the vacuum transfer module VTM. However, in the present embodiment, even when particles are generated from the reaction product deposited on the inner wall 22 of the vacuum transfer module VTM, the particles in contact with the inner wall 22 are adsorbed and removed by the ionic liquid 23 held on the inner wall 22. Accordingly, the adhesion of particles onto the wafer W is suppressed.

Depending on the constituent material of the vacuum transfer module VTM, particles may be generated from the constituent material itself of the inner wall 22 of the vacuum transfer module VTM. Even in that case, since the inner wall 22 of the vacuum transfer module VTM is covered with the ionic liquid 23, particles are prevented from scattering from the constituent material of the inner wall 22 into the atmosphere of the vacuum transfer module VTM and, also, it is possible to adsorb and remove the particles in the atmosphere.

### (Adsorption Effect of Particles by the Ionic Liquid)

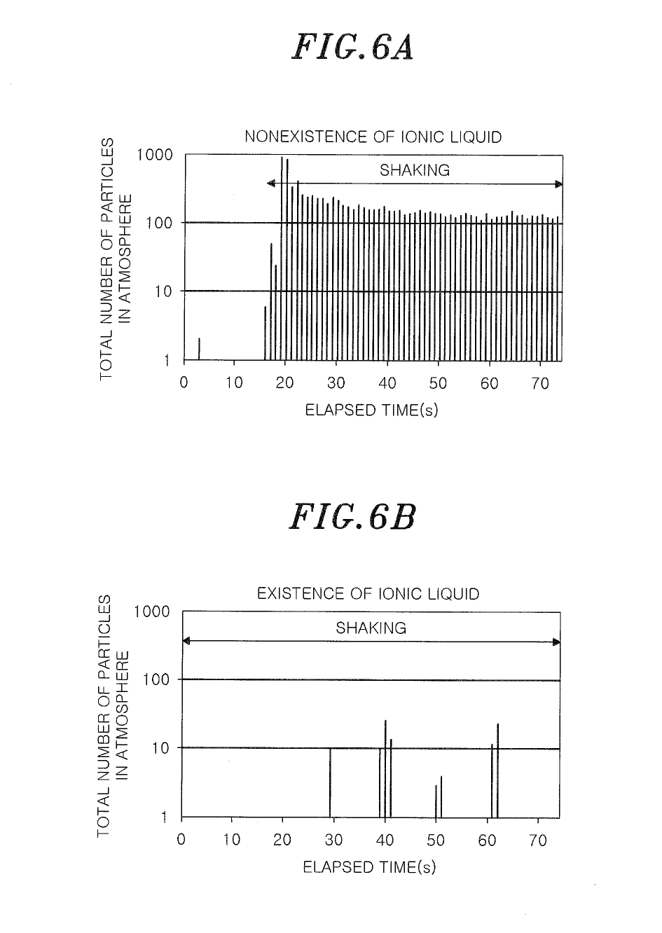

The effect of adsorbing and removing particles in an atmosphere by the ionic liquid 23 will be described by using a result of a comparative test. FIG. 6A explains a total number of particles in the atmosphere in a reference embodiment and shows the measurements obtained in a state without the ionic liquid 23. FIG. 6B explains a total number of particles in the atmosphere in one embodiment and shows the measurements obtained in a state with the ionic liquid 23. In FIGS. 6A and 6B, the vertical axis represents the total number of particles in the atmosphere, and the horizontal axis represents elapsed time.

In the comparative test, particles of about 1 μm were made to flow into a straight pipe used as a transfer chamber from an upstream side of the straight pipe, and the total number of particles was detected by a particle measuring device (particle counter) disposed at a downstream side of the straight pipe. In the comparative test, as a simple acceleration test, a particle pool for testing was provided at the upstream side of the straight pipe, and a large number of particles were continuously generated forcibly by shaking the particle pool. In one embodiment shown in FIG. 6B, a clean paper impregnated with methyltrioctylammonium bis (trifluoromethylsulfonyl) imide was adhered to an inner circumferential surface of the straight pipe.

As shown in FIG. 6A, in the reference embodiment, during the shaking of the particle pool, the total number of particles generated in the atmosphere in the straight pipe exceeded 100. On the other hand, in one embodiment, as shown in FIG. 6B, particles were not generated until about seconds elapsed from the start of the shaking of the particle pool. Then, particles were intermittently generated. However, the total number of particles in the atmosphere in the straight pipe was about 10. In other words, in one embodiment, a large number of particles generated by shaking the particle pool was adsorbed and removed by the ionic liquid 23, and the amount of particles generated in the atmosphere in the straight pipe was considerably suppressed.

### (Transfer Method)

In the transfer method according to the embodiment using the above-described transfer apparatus 20, the ionic liquid 23 for adsorbing particles in the atmosphere in the vacuum transfer module VTM is held on the inner wall 22 of the vacuum transfer module VTM to which the wafer W processed in the process module PM is transferred, and then the wafer W is transferred in the vacuum transfer module VTM.

The transfer apparatus 20 of the above-described embodiment includes the vacuum transfer module VTM to which the wafer W processed in the process module PM is transferred and the ionic liquid 23 for adsorbing particles in an atmosphere in the vacuum transfer module VTM while being held on the inner wall 22 of the vacuum transfer module VTM. Thus, the particles in the atmosphere of the vacuum transfer module VTM are removed by the ionic liquid 23. Accordingly, the adhesion of particles onto the wafer W can be suppressed. As a result, the productivity of the wafer W can be improved, and the quality of the processing state of the wafer W can be enhanced.

Further, in the transfer apparatus 20 of the embodiment, the ionic liquid 23 is held on the entire inner wall 22 of the vacuum transfer module VTM. Accordingly, particles in the atmosphere of the vacuum transfer module VTM can be effectively adsorbed by the ionic liquid 23, and the adhesion of particles onto the wafer W can be effectively suppressed.

Further, the liquid holding member 24 for holding the ionic liquid 23 is provided on the inner wall 22 of the vacuum transfer module VTM of the transfer apparatus 20 of the embodiment. Accordingly, the liquid holding member 24 impregnated with the ionic liquid 23 is attached to the inner wall 22, and the ionic liquid 23 can be properly held on the inner wall 22.

Further, the liquid holding member 24 of the transfer apparatus 20 of the embodiment is provided at the handling device ARM. Therefore, as the handling device ARM for transferring the wafer W in the vacuum transfer module VTM is moved, particles in the atmosphere in the vacuum transfer module VTM can be adsorbed and removed by the ionic liquid 23. Accordingly, the adhesion of particles onto the wafer W can be further suppressed.

Moreover, the liquid holding member 24 of the transfer apparatus 20 of the embodiment is made of a porous material. Therefore, the ionic liquid 23 can be properly held by the liquid holding member 24.

The inner wall 22 of the vacuum transfer module VTM of the transfer apparatus 20 of the embodiment has the irregularities 25 for holding the ionic liquid 23. Accordingly, the ionic liquid 23 can be held by the irregularities 25 of the inner wall 22 by coating the ionic liquid 23 on the inner wall 22.

In the transfer apparatus 20 of the embodiment, the ionic liquid 23 has a hydrophobic property. Accordingly, it is possible to suppress the decrease in a vacuum degree in the vacuum transfer module VTM, and also possible to allow the ionic liquid 23 to be properly held by the liquid holding member 24 by suppressing the decrease in the viscosity of the ionic liquid 23. By using ionic liquid 23 that is water-insoluble and does not react with water, the decrease in the vacuum degree in the vacuum transfer module VTM can be suppressed and the ionic liquid 23 can be properly held by the liquid holding member 24. In addition, since the reaction between the ionic liquid 23 and water is avoided, the effect on the environment and the human body can be suppressed, and the durability of the vacuum transfer module VTM can be properly ensured.

As for the processing chamber of the semiconductor manufacturing apparatus of the present disclosure, it is possible to use other apparatuses as well as a capacitively coupled plasma (CCP) apparatus. Other apparatuses may be, e.g., an inductively coupled plasma (ICP) apparatus, a plasma processing apparatus using a radial line slot antenna, a helicon wave plasma (HWP) apparatus, an electron cyclotron resonance plasma (ECR) apparatus or the like. The processing chamber may be a plasma-less apparatus for performing etching or film formation by using a reactant gas and heat.

In the present embodiment, the semiconductor wafer W that is a substrate is used as a target object. However, it is also possible to use various substrates used for, e.g., Liquid Crystal Display (LCD), Flat Panel Display (FPD) and the like, a photomask, a CD substrate, a printed board, or the like.

While the disclosure has been shown and described with respect to the embodiments, it will be understood by those skilled in the art that various changes and modifications may be made without departing from the scope of the disclosure as defined in the following claims.

What is claimed is:

1. A transfer apparatus comprising:
a transfer chamber to which a target object processed in a processing chamber is transferred; and
an ionic liquid, held on an inner wall of the transfer chamber, configured to adsorb particles in an atmosphere in the transfer chamber.

2. The transfer apparatus of claim 1, wherein the ionic liquid is held on an entire surface of the inner wall of the transfer chamber.

3. The transfer apparatus of claim 1, further comprising a load-lock chamber configured to switch an atmosphere in the transfer chamber between an atmospheric pressure state and a vacuum pressure state.

4. The transfer apparatus of claim 1, wherein a liquid holding member configured to hold the ionic liquid is provided at the inner wall of the transfer chamber.

5. The transfer apparatus of claim 4, further comprising:
a transfer mechanism configured to transfer the target object,
wherein the liquid holding member is provided at the transfer mechanism.

6. The transfer apparatus of claim 4, wherein the liquid holding member is made of a porous material.

7. The transfer apparatus of claim 6, wherein the liquid holding member is paper or a sponge sheet.

8. The transfer apparatus of claim 1, wherein irregularities configured to hold the ionic liquid are formed on the inner wall of the transfer chamber.

9. The transfer apparatus of claim 1, wherein the ionic liquid is hydrophobic.

10. The transfer apparatus of claim 1, wherein the ionic liquid is water-insoluble and does not react with water.

11. The transfer apparatus of claim 1, wherein the ionic liquid is at least one of methyltrioctylammonium thiosalicylate, trihexyltetradecylphosphonium bis (2-ethylhexyl) phosphate, methyl trioctyl ammonium bis (trifluoromethylsulfonyl) imide, 1-ethyl-3-methylimidazolium bis (trifluoromethylsulfonyl) imide, 1-butyl-3-methylimidazolium bis (trifluoromethylsulfonyl) imide, 1-hexyl-3-methylimidazolium bis (trifluoromethylsulfonyl) imide, and 1-methyl-1-propylpyrrolidinium bis (trifluoromethylsulfonyl) amide.

12. A transfer method comprising:
holding ionic liquid, for adsorbing particles in an atmosphere in a transfer chamber to which a target object processed in a processing chamber is transferred, on an inner wall of the transfer chamber,
and transferring the target object in the transfer chamber.
